(19) United States
(12) Patent Application Publication
(10) Pub. No.: US 2005/0260828 A1
(43) Pub. Date: Nov. 24, 2005

(54) Bonding method, bonding apparatus and sealing means

(75) Inventor: Mitsuhiro Yuasa, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: TOKYO ELECTRON LIMITED

(21) Appl. No.: 10/766,213

(22) Filed: Jan. 29, 2004

(30) Foreign Application Priority Data
Jan. 30, 2003 (JP) 2003-022553(PAT.

(51) Int. Cl. H01L 21/46

(52) U.S. Cl. 438/455

(57) ABSTRACT

A silicon substrate in which MEMS devices are formed and a quartz substrate used to seal the silicon substrate are tentatively bonded to each other. While the silicon substrate and quartz substrate are being pressed using a pressure jig, light having a wavelength that is absorbed into the silicon substrate but not into the pressure jig and quartz substrate is radiated from light sources to the interface between the silicon substrate and quartz substrate. Thus, the interface is heated and the silicon substrate and quartz substrate are bonded.

### BACKGROUND OF THE INVENTION

1. Field of the Invention

The present invention relates to a device packaging technology or a bonding technology and, more particularly, to a packaging technology or a bonding technology adaptable to micro-electromechanical-system (MEMS) devices.

2. Description of the Related Art

As many micro-machines or micro-electromechanical-system (MEMS) devices have a fragile structure due to inclusion of a movable member in a chip, if they were, unlike semiconductors, sealed before being forwarded to a dicing process, it would be advantageous. An attempt has been made to perform packaging during a wafer machining process in the past.

For example, MEMS components formed in a silicon wafer are covered with a cover glass, and the silicon wafer and the cover glass are bonded and then packaged. For bonding different kinds of materials, anode bonding is generally adopted.

FIG. 6 is a conceptual diagram of anode bonding. Anode bonding is a technology for bonding a cover glass and silicon. Specifically, a cover glass 20 (SiO₂—Al₂O₃—Na₂O or the like) containing a sodium impurity is placed on to a silicon wafer 10 loaded on a supporting stage 3, and pressurized using a pressurization jig 40. With the temperature raised to several hundred of degrees (normally about 400° C.), an electric field ranging from 500 V to 1000 V is applied to the silicon wafer 10 and glass 20. Ion migration in the glass is utilized in order to produce SiO—at the interface between the silicon wafer and glass. In other words, when a dc power supply 50 is used to apply a voltage to a united body of silicon and a glass, since the silicon serves as an anode and the glass serves as a cathode, sodium contained in the glass moves toward the glass because sodium comprises cations. Moreover, a space-charge layer containing anions of SiO— is formed on the interface between the glass and silicon. Consequently, a large electrostatic attraction appears at the interface. This results in a covalent bond.

Moreover, a cold bonding technology has also been proposed so that bonding can be achieved without heating to a high temperature. In this case, the bonded surfaces of two substrates are cleaned in plasma or with an ion beam and activated. Thereafter, the substrates are bonded to each other at room temperature. Furthermore, according to another method, after the substrates are bonded at room temperature, they are heated in a furnace so that they will be firmly bonded (refer to, for example, Japanese Unexamined Patent Application Publication No. 2002-64268).

However, anode bonding requires heating at several hundreds of degrees on Celsius scale. After samples are disposed in place, it takes much time (several hours or so) to raise or lower the temperature with application of a pressure or a voltage. This contradicts the concept of a mass production technology. Moreover, the anode bonding can be adapted only to materials whose coefficients of thermal expansion are nearly the same in a range from room temperature to several hundreds of degrees on Celsius scale. Furthermore, sodium adversely affects semiconductor circuits. There is therefore difficulty in adapting the anode bonding to MEMS devices that coexist with semiconductor devices.

Moreover, regarding cold bonding, the bonding force is dominated by an intermolecular force working at the interface between two substrates. The bonding force is insufficient to bond some combinations of materials to each other. Moreover, when the cold bonding is adapted to devices that are supposed to be employed in a severe environment in terms of temperature or vibration, it cannot offer sufficient reliability.

Furthermore, the method where substrates are heated in a furnace after being joined at room temperature has, similarly to the anode bonding, drawbacks that the process requires a long time and that the coefficients of thermal expansion of the substrates must be the same. When chips having MEMS devices formed therein are heated to a high temperature, they may be bonded firmly. However, the MEMS devices formed in the chips are damaged.

### SUMMARY OF THE INVENTION

Accordingly, an object of the present invention is to provide a bonding method capable of firmly bonding substrates, of which the coefficients of thermal expansion are different from each other, using a quick process.

In order to accomplish the above object, according to the present invention, there is provided a method and apparatus for bonding a first substrate and a second substrate by radiating light, having a wavelength that is absorbed into the first substrate but not into the second substrate, onto the interface between the first and second substrates.

For better bonding, the first substrate and second substrate should be pressed. A pressure member for pressing the first and second substrates may include a sensor that measures an applied pressure. Moreover, a temperature adjustment device may be disposed near one side of the first substrate and opposite to the side onto which light is radiated.

As the second substrate, a sealing member made of quartz, glass, or resin may be adopted. The sealing member may have the same shape as a wafer does and have an alignment mark inscribed therein. Moreover, the sealing member may have recesses that prevent interference with MEMS components. Furthermore, the sealing member may have a light shielding material applied to part thereof except the surface for bonding. A plastic film having thermoplasticity or a plastic film coated with an adhesive that adheres to a substrate when illuminated with radiated light may be adopted as the sealing member.

According to the present invention, substrates whose coefficients of thermal expansion are different from each other can be firmly bonded during a quick process without the necessity of heating to a high temperature or for a long period of time.

### BRIEF DESCRIPTION OF THE DRAWINGS

Other features and advantages will become apparent in discussion of the embodiments of the invention in relation to the following drawings.

FIG. 1 schematically shows a bonding apparatus in accordance with one embodiment of the present invention;

FIG. 2A is a schematic front view of a sealing member employed in the embodiment of the present invention;

FIG. 2B is a schematic sectional view of the sealing member;

FIG. 3 schematically shows a tape-like plastic film employed in other embodiment as the sealing member included in the present invention;

FIG. 4 is a schematic sectional view showing the bonded states of the tape-like plastic film and a silicon substrate 1 included in the present invention;

FIG. 5 is a schematic sectional view showing a thermoplastic film employed in other embodiment as the sealing member included in the present invention; and

FIG. 6 schematically shows the concept of conventional anode bonding.

### DESCRIPTION OF THE PREFERRED EMBODIMENTS

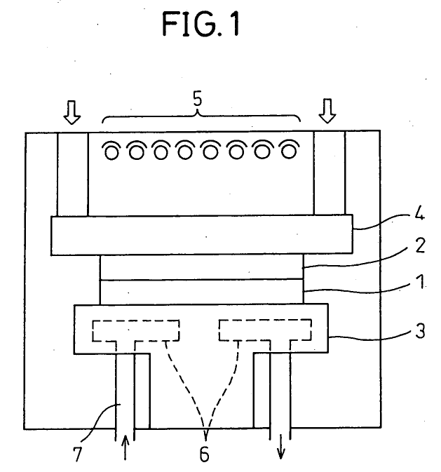

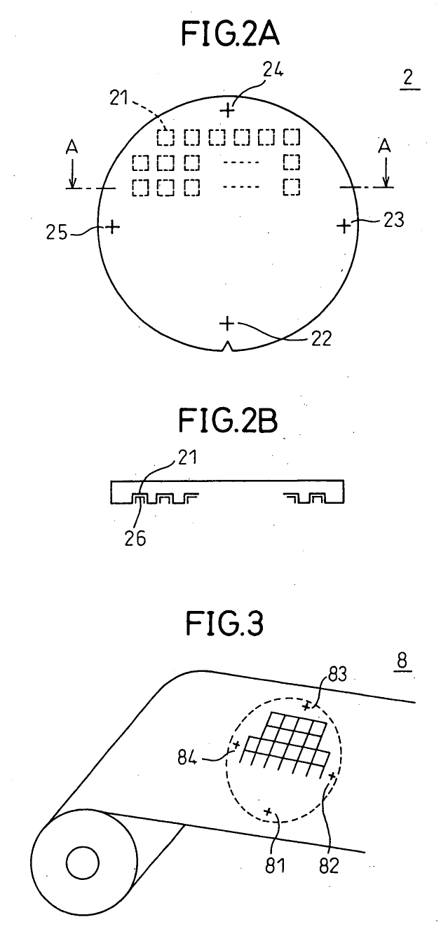

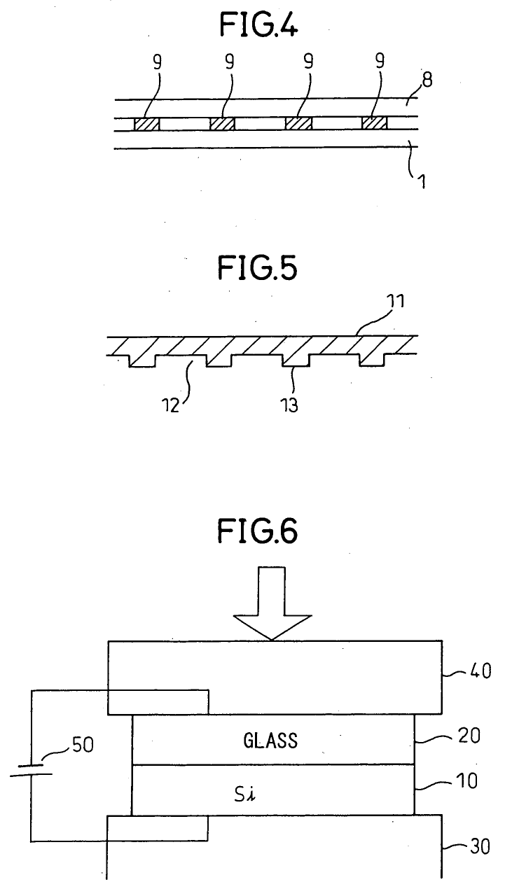

Embodiments of the present invention will be described with reference to the drawings. An embodiment shown in FIG. 1 and FIG. 2 packages a silicon substrate, in which MEMS components are formed, using a quartz sealing member.

FIG. 1 schematically shows a bonding apparatus in accordance with one embodiment of the present invention. FIG. 2A is a schematic front view of a sealing member made of quartz, and FIG. 2B schematically shows an A-A cutting plane of the sealing member.

Chips each of which has a size of, for example, 5-mm-square and has MEMS members formed therein, that is, an MEMS device formed therein is defined on a silicon substrate 1. A quartz substrate 2 serving as a sealing member, located the silicon substrate 1, has, as shown in FIGS. 2A and 2B, the same shape as this silicon substrate. The quartz substrate 2 has recesses 21, each of which has a size of 5-mm-square, formed therein for fear the quartz substrate may interfere with the MEMS components in the chips arranged on the silicon substrate 1. Moreover, alignment marks 22 to 25 are inscribed on the quartz substrate 2. If the side of the silicon substrate 1 to be joined to the quartz substrate is higher than the tops of the MEMS components, that is, if the quartz substrate will not interfere with the MEMS components, the recesses 21 need not be formed in the quartz substrate. Moreover, a light shielding material 26 is applied to the internal surfaces of the recesses.

In the present embodiment, the silicon substrate 1 and quartz substrate 2 are tentatively bonded to each other at a step preceding a step of introducing them to the bonding apparatus. During the tentative bonding, the surfaces of the silicon substrate 1 and sealing member 2 are cleaned in Ar plasma and brought into contact with each other on the basis of the alignment marks 22 to 25. In the present embodiment, the substrates are cleaned in Ar plasma and then tentatively bonded to each other. This tentative bonding is not required but the substrates may be merely aligned with each other and then brought into contact with each other.

As shown in FIG. 1, the bonding apparatus comprises a stage 3 on which the substrates 1 and 2 to be bonded are loaded, a pressure device 4 that presses the substrates 1 and 2, and lamps 5 that radiate light to the interface between the substrates 1 and 2. The silicon substrate 1 and quartz substrate 2 that have been tentatively bonded to each other are secured with the silicon substrate 1 placed on the stage 3. The stage 3 has a vacuum or electrostatic chuck (not shown) that holds the silicon substrate and fixes it to the stage 3. Moreover, a temperature adjustment device 6 that cools the substrates by passing a coolant 7 is incorporated in the stage 3. While the temperature adjustment device is in operation, the temperature of the substrates is adjusted to be retained at, for example, 20° C. A sensor for use in adjusting the temperature may be of a type that detects the temperature of the coolant or of a type that measures the temperature of the substrates. While the substrates are being pressed with a quartz jig, that is, the pressure device 4 put on the quartz substrate, the lamps 5 located near the pressure device 4 are lit to radiate light to the substrates. Thus, the silicon substrate 1 and quartz substrate 2 are bonded.

The pressure device 4 has a pressure sensor (not shown). At least before bonding work is started, an applied pressure is measured at three or more points in order to check whether the applied pressure is uniform. The pressure sensor may be of a type that directly senses the pressure applied to the substrates or of a type that checks an output of a pressure mechanism that presses a substrate at many points.

Light having a wavelength that is radiated from the lamps 5 is hardly absorbed into both the pressure device 4 that is a quartz jig and the quartz substrate 2 that is a sealing member but the light is absorbed into the silicon substrate 1. Consequently, the quartz substrate 2 is not heated and is, therefore, not thermally expanded. On the other hand, light is absorbed into the surface of the silicon substrate 1. Therefore, the surface thereof, that is, the interface between the quartz substrate 2 and silicon substrate 1 is activated, and oxygen molecules contained in the silicon and quartz substrates form an intense covalent bond. The silicon substrate 1 is cooled and light is absorbed into the surface thereof. Therefore, the silicon substrate 1 itself will not be heated. Consequently, the silicon substrate 1 will not be thermally expanded. Moreover, the heating of the surface by the lamps 5 persists for a very short period of time. The time required for this process can be short.

Furthermore, as the light shielding material 26 is applied to the bottoms and walls of the recesses to prevent light being radiated to the MEMS components, light is not radiated to components that need not be heated. The MEMS components or semiconductor circuits are therefore prevented from being adversely affected by radiated light. Needless to say, the light shielding material 26 is not required. Whether the light shielding material 26 is applied or the places where the light shielding material is applied should be determined in consideration of various conditions.

In the present embodiment, the silicon substrate 1 is placed on the stage 3. Alternatively, the quartz substrate 2 may be placed on the stage 3. In this case, the stage 3 is made of a material that does not absorb radiated light so that light will pass through the stage and be radiated to the interface between the silicon substrate 1 and quartz substrate 2. In either case, the substrates are arranged so that light will pass through a substrate which does not absorb the light and will then be radiated to the interface between the substrates. Moreover, in the present embodiment, quartz is adopted as the material of the sealing member. Alternatively, a glass or a resin will serve.

FIG. 3 shows a tape-like plastic film 8 employed in other embodiment as the sealing member. The tape-like plastic film 8 is different from the sealing member employed in the aforesaid embodiment in a point that predetermined parts thereof are coated with an adhesive. Alignment marks 81 to 84 used to align the plastic film 8 with the silicon substrate 1 are inscribed on the plastic film 8. Sections each having a size of 5-mm-square are defined on the plastic film 8 in association with the MEMS chips each of which has the size of 5-mm-square and which are defined on the silicon substrate. The adhesive is applied in advance to the perimeters of the sections.

FIG. 4 is a schematic sectional view showing the plastic film 8 bonded to the silicon substrate 1 using the adhesive 9. The adhesive 9 is applied to the perimeters of the sections having the size of 5-mm-square.

The plastic film 8 is wound and held as shown in FIG. 3. When the plastic film 8 becomes necessary for packaging during a wafer machining process, it is pulled out and aligned with a silicon substrate using the alignment marks 81 to 84. The silicon substrate 1 having the MEMS components formed therein is thus covered. The silicon substrate 1 covered with the plastic film 8 aligned therewith is placed on a stage. While the silicon substrate covered with the plastic film is being pressed by a pressure member, light is radiated to the plastic film 8 in order to heat the adhesive 9. Consequently, the plastic film 8 is bonded to the silicon substrate 1.

The plastic film 8 does not absorb light similarly to the counterpart employed in the previous embodiment. In the present embodiment, the adhesive 9 may absorb light. In either case, radiated light heats the surface of the silicon substrate 1 or the adhesive 9. Consequently, the adhesive 9 applied to joint portions of the plastic film 8 is heated and can adhere to the silicon substrate. Consequently, the silicon substrate 1 and plastic film 8 are bonded. Thereafter, the plastic film 8 is cut apart along the contour of the silicon substrate 1. Thus, packaging using the plastic film 8 is completed. Incidentally, after the plastic film 8 is aligned with the silicon substrate and brought into contact therewith, the plastic film may be cut apart before being bonded to the silicon substrate.

FIG. 5 is a schematic sectional view of a thermoplastic film 11 employed as a sealing member in other embodiment of the present invention. A bonding method itself is identical to that applied to the plastic film shown in FIG. 3 and FIG. 4. The bonding method therefore will not be described. The thermoplastic plastic film 11 employed in the present embodiment has recesses 12 but does not have an adhesive layer. A number of recesses 12 are formed in association with chips arranged on a silicon substrate for fear the plastic film may interfere with MEMS components formed in the chips when it covers the silicon substrate. The thermoplastic plastic film 11 is, like the one employed in the aforesaid embodiment, made of a material that does not absorb light. Consequently, when the thermoplastic plastic film 11 is brought into contact with the silicon substrate, pressed, and illuminated with radiated light, the silicon substrate is heated but the thermoplastic plastic film is not. The heat of the silicon substrate is transmitted to projections 13 of the thermoplastic plastic film that surround the recesses 12. Consequently, the part of the plastic film in contact with the silicon substrate is melted to cause the plastic film and silicon substrate to join.

If a light shielding material similar to the one shown in FIG. 2B is applied to part of the plastic film 8 other than the part thereof having the adhesive 9, unnecessary light will not be radiated to MEMS circuits or the like.

1. A bonding method comprising the steps of:
bringing a first substrate and a second substrate into contact with each other; and
radiating light having a wavelength that is absorbed into said first substrate but not into said second substrate, to the interface between said first substrate and said second substrate for bonding said first substrate and said second substrate.

2. A bonding method according to claim 1 wherein, at said bonding step, said first substrate and said second substrate are pressed.

3. A bonding apparatus for bringing a first substrate and a second substrate into contact with each other for bonding them, comprising:
a light radiating device that radiates light having a wavelength that is absorbed into said first substrate but not into said second substrate, to the interface between said first substrate and said second substrate.

4. A bonding apparatus according to claim 3, further comprising a pressure device that is made of a material which does not absorb the light and that presses said first substrate and said second substrate.

5. A bonding apparatus according to claim 4, further comprising a sensor that measures a pressure applied by said pressure device.

6. A bonding apparatus according to claim 3, further comprising a temperature adjustment device located near one side of said first substrate opposite to the side to which light is radiated.

7. A sealing member that is employed as said second substrate according to the bonding method set forth in claim 1 and that is made of quartz, glass, or resin.

8. A sealing member according to claim 7, wherein said sealing member has the same shape as said first substrate and has alignment marks inscribed therein.

9. A sealing member according to claim 7, wherein said sealing member has recesses that prevent interference with members formed in said first substrate.

10. A sealing member according to claim 7, wherein said sealing member has a light shielding material applied to predetermined part thereof.

11. A sealing member that is employed as said second substrate according to the bonding method set forth in claim 1 and that is realized with a plastic film having thermoplasticity.

12. A sealing member according to claim 11, wherein said sealing member has alignment marks inscribed therein.

13. A sealing member according to claim 11, wherein said sealing member has a light shielding material applied to predetermined part thereof.

14. A sealing member that is employed as said second substrate according to the bonding method set forth in claim 1 and that has an adhesive which adheres to said first substrate when illuminated with light.

15. A sealing member according to claim 14, wherein said sealing member has alignment marks inscribed therein.

16. A sealing member according to claim 14, wherein said sealing member has a light shielding material applied to predetermined part thereof.

17. A sealing member according to claim 14, wherein said adhesive itself is heated with radiated light to adhere to said first substrate.

18. A sealing member according to claim 14, wherein when said first substrate is heated with radiated light, said adhesive is heated to adhere to said first substrate.
